(19) United States
(12) Patent Application Publication
(10) Pub. No.: US 2014/0035001 A1
(43) Pub. Date: Feb. 6, 2014

(54) COMPOUND SEMICONDUCTOR STRUCTURE

(71) Applicants: Lukas Czornomaz, Rueschlikon (CH); Mario El Kazzi, Rueschlikon (CH); Jean Fompeyrine, Rueschlikon (CH); Chiara Marchiori, Rueschlikon (CH)

(72) Inventors: Lukas Czornomaz, Rueschlikon (CH); Mario El Kazzi, Rueschlikon (CH); Jean Fompeyrine, Rueschlikon (CH); Chiara Marchiori, Rueschlikon (CH)

(73) Assignee: INTERNATIONAL BUSINESS MACHINES CORPORATION, Armonk, NY (US)

(21) Appl. No.: 13/565,106

(22) Filed: Aug. 2, 2012

(51) Int. Cl. H01L 29/78; H01L 21/20

(52) U.S. Cl. 257/192; 438/478; 257/E29.255; 257/E21.09

(57) ABSTRACT

A semiconductor structure (1) comprises a dielectric layer (2) including a dielectric material having a dielectric constant higher than that of silicon oxide; a channel region (3) including a compound semiconductor material; a passivation layer (4) including a passivation material between the channel region (3) and the dielectric layer (2); and a barrier layer (5) including a barrier material between the dielectric layer (2) and the passivation layer (4) for reducing a chemical reaction of the dielectric material of the dielectric layer (2) with the passivation material of the passivation layer (4).

### FIELD OF INVENTION

This disclosure relates to a semiconductor structure, and more particularly to a semiconductor structure including a dielectric material having a dielectric constant of greater than that of silicon dioxide, as for example a hafnium-based dielectric, and a compound semiconductor. This disclosure also provides a method of fabricating such a semiconductor structure.

### BACKGROUND

In conventional semiconductor technology silicon (Si) is the principal semiconductor material and silicon dioxide (SiO₂) is used as gate oxide material in CMOS transistors. However, the continuous downscaling of semiconductor devices requires better dielectrics than SiO₂ to achieve a thinner gate dielectric with acceptable leakage currents. Such dielectrics are called high-k dielectric materials. Additionally, alternative semiconductor materials having a higher charge carrier mobility than Si are required to follow the international technology roadmap for semiconductors (ITRS).

Candidates as alternative semiconductor material are, in particular, compound semiconductors. One class of compound semiconductors are comprised of at least one element from Group IIIA and Group VA of the periodic table of elements. Such compound semiconductors including an element from Group IIIA and VA are often referred to as III-V or III/V compound semiconductors. Illustrative examples of compound semiconductors, comprising III-V compound semiconductors include, but are not limited to: GaAs, InGaAs, InP, InAs, GaP, InSb, GaSb and/or GaN.

GaAs being a promising alternative semiconductor material, however, does not have a natural oxide so that standard CMOS techniques cannot be employed. It is therefore desirable to provide GaAs substrates with high-k dielectric materials as gate dielectrics. Direct deposition of high-k dielectrics on GaAs or compounds semiconductors usually results in unpassivated surfaces with a high density of undesired interface traps and, hence, a poor interface between the semiconductor compound and the dielectric. Such a poor interface is directly related to degraded device performances. It is therefore common to fabricate structures with an interface control layer located between the high-k dielectric and the compound semiconductor surface.

M. Akazawa and H. Hasegawa, “Formulation of ultrathin SiNₓ/Si interface control double layer on (001) and (111) GaAs surfaces for ex situ deposition of high-k dielectrics”, J. Vac. Sci. Technol. B 25(4), July/August 2007, 1481-1490, discloses for example a combination of HfO₂ as a high-k dielectric with a GaAs substrate where a Si interface control layer is located between the dielectric and the GaAs and a buffer layer consisting of SiₓN_{y} is arranged between the HfO₂ and the Si interface control layer for preventing subcutaneous oxidation of the GaAs. HfO₂ is deposited ex situ onto the buffer layer.

R. Katamreddy et al., “Controlling interfacial reactions between HfO₂ and Si using ultrathin Al₂O₃ diffusion barrier”, Applied Physics Letters 89, 262906-1-262906-3 (2006), disclose an aluminum oxide barrier layer between a HfO₂ film and a crystalline Si substrate. Similarly, H Jin et al., “Thermal stability of Al₂O₃—HfO₂ laminate, Hf—Al—O alloy and HfO₂ thin films on Si”, Journal of the Korean Physical Society, Vol. 46, May 2005, pp S52-S55, disclose Al₂O₃—HfO₂ laminates on p-Si (100).

### BRIEF SUMMARY OF THE INVENTION

It is an aspect of the present disclosure to provide semiconductor structures based on a compound semiconductor material and a high-k dielectric. Other aspects relate to methods for fabricating such a semiconductor structure.

According to an embodiment of a first aspect of the invention a semiconductor structure is disclosed, wherein the semiconductor structure comprises:

a dielectric layer including a dielectric material having a dielectric constant higher than that of silicon oxide;

a channel region including a compound semiconductor material;

a passivation layer including a passivation material between the channel region and the dielectric layer; and

a barrier layer including a barrier material between the dielectric layer and the passivation layer for reducing a chemical reaction of the dielectric material of the dielectric layer with the passivation material of the passivation layer.

The dielectric material has a higher dielectric constant than conventional SiO₂ which has a dielectric constant κ=3.9. The dielectric materials used herein can be referred to as high-k materials.

The relatively thin barrier layer between the dielectric layer and the passivation layer may suppress at least partly a reaction of the two constituent materials of the dielectric and passivation layer. Preferably, the barrier material is chemically stable against reaction with the passivation material during a fabrication of the semiconductor structure. The barrier material can be chosen as to be stable with respect to the passivation material during process steps involved in forming the dielectric layer and preferably during consequent steps for forming gates on the dielectric layer and/or device processing.

The compound semiconductor material of the channel region preferably includes a III-V compound semiconductor material, a II-VI compound semiconductor material, and/or a IV-IV compound semiconductor material. For example, the compound semiconductor material is InₓGa₍₁₋ₓ₎As where 0<x<1, InP, GaP, InSb, GaSb, ZnSe, CdTe, SiC, SiGe and/or GaN. In particular, InGaAs and/or GaAshas a higher carrier mobility than silicon and allows for fast semiconductor devices.

The channel region, which can be part of a semiconductor substrate, preferably includes a doped semiconductor material as, for example a p- or n-type GaAs material.

In some embodiments of the semiconductor structure the compound semiconductor material is replaced by germanium (Ge). Although, Ge is strictly not a compound semiconductor, the disclosed features for a semiconductor structure and the methods may also hold for Ge-based devices.

According to one embodiment of the semiconductor structure the passivation material of the passivation layer includes amorphous silicon. Si may improve the interface properties of the compound semiconductor material with the dielectric material. Further, an amorphous silicon layer can be deposited by standard processes.

According to another embodiment of the semiconductor structure the bather material of the barrier layer includes metal oxides or metal-nitrides, where the metal Me can be, but is not limited to, Al, Y, Sc, Gd, Dy, La, Lu, Ce or LaAl. According to a further embodiment the barrier material includes an element, a binary or ternary compound that is thermodynamically stable in contact with Si, which may be used as a passivating material. Another aspect of the barrier material is its preferred ability to screen Si from a reaction with a high-k dielectric. A preferred version of the barrier layer consists of Al₂O₃ which can comprise only few mono layers on an amorphous Si passivation layer. The barrier layer, in particular reduces, or more preferably prevents, a silicate formation.

In embodiments the dielectric material of the dielectric layer includes a hafnium-based dielectric. However, also other high-k dielectric materials, such as metal oxides, e.g. La₂O₃, can be contemplated.

According to an embodiment, the barrier material and the dielectric material are chosen as to at least partially prevent the formation of silicon dioxide, silicates or silicides.

The semiconductor structure can be seen as a—optionally processed—compound semiconductor substrate, which is passivated by a passivation material layer, and carries a first and a second high-k dielectric layer, wherein the first high-k layer acts as a barrier layer for the second high-k layer.

In embodiments, the semiconductor structure further comprises a gate arrangement located on the dielectric layer. Then, the semiconductor structure may be referred to as a gate stack arrangement of a CMOS or MOSFET structure.

In other embodiments a capacitance between the gate arrangement and the channel region is greater than 2 microfarad per square centimeter. Preferably, the respective gate capacitance is greater than 2.5 microfarad per square centimeter, and even more preferred the capacitance is greater than 3.0 microfarad per square centimeter. Consequently, the semiconductor structure may allow for the formation of a FET having high carrier mobility and low source-to-drain leakage currents.

According to some embodiments the barrier layer has a thickness of less than 1.5 nanometers, and preferably less than 1.0 nanometer. The thickness of the barrier layer, in particular, can be between one and five atomic layers.

According to some embodiments the passivation layer has a thickness of less than 1.5 nanometers, and preferably less than 1.0 nanometer. The thickness of the passivation layer, in particular, can be between one and five atomic layers.

The sum of the thicknesses of the barrier layer and the passivation layer (combined thickness) may be less than 2.5 nanometers, preferably the combined thickness is less than 2.0 nanometers, and even more preferably the combined thickness is less than 1.5 nanometers.

According to some embodiments the dielectric layer has a thickness between 0.5 and 10 nanometers. Preferably, the dielectric layer has a thickness of less than 5.0 nanometers. For example, an Hf-based dielectric layer can have a thickness between 1 and 7 nanometers. A preferred embodiment comprises a HfO₂ dielectric layer having a thickness of approximately 2 nm.

According to an embodiment of a second aspect of the invention a method for fabricating a semiconductor structure, as, for example, the above-depicted semiconductor structure, may comprise:

providing a substrate including a compound semiconductor material;

depositing a passivation material on the substrate for forming a passivation layer including a passivation material;

depositing a barrier material on the passivation layer for forming barrier layer; and

depositing a dielectric material having a dielectric constant that is greater than that of silicon oxide on the barrier layer for forming a dielectric layer;

wherein the barrier material is adapted to reduce a chemical reaction of the dielectric material of the dielectric layer with the passivation material of the passivation layer.

The material and structural properties of the substrate, passivation, barrier and dielectric layer are, in particular, as described above with respect to the aspects and embodiments of the semiconductor structure.

The method may further comprise: processing the substrate for forming a hetero structure. Processing may also include forming integrated circuit devices including one or more of the semiconductor structure. The method may be part of a manufacturing process for integrated circuit chips.

Additionally, the method may further comprise: depositing a conducting material on the dielectric layer and/or on the substrate for forming contacts. For example, lithographic techniques for fabricating contacts and/or pads.

The method may further comprise: cleaning the substrate including exposing or subjecting the substrate with hydrogen fluoride and/or exposing the substrate to a hydrogen plasma.

For example, by subjecting a III-V compound semiconductor material to a cleaning step any native oxides such as, Ga₂O₃ or As₂O₅, may be removed from the surface of the III-V compound semiconductor material. As a result of the cleaning one can provide a treated surface that typically remains unpinned. The cleaning may be performed by a desorption process or, preferably, by an H plasma process. An amorphous semiconducting layer as the passivation layer is preferably formed in-situ on the treated surface of the III-V compound semiconductor material.

In embodiments of the method the method is performed in-situ in an ultra high vacuum. Processing in a vacuum chamber may in particular reduce the risk of having silicon oxides that may decrease the capacitance of the gate capacitance. It is understood that ultra-high vacuum (UHV) corresponds to pressures lower than about 10⁻⁷ pascal. By an in-situ treatment a contamination of the sample and/or oxidation of the substrate may be avoided.

By employing the barrier layer in the proposed semiconductor structure and the method for fabricating the same, in particular embodiments a silicate formation may be suppressed. Then, the capacitance associated to the high-k layer is predominantly determined by the physical thickness and by the dielectric constant of the high-k oxide. This may lead to the formation of a gate stack with high capacitance. Also SiO₂ formation is reduced, which allows for thin Si passivating layers to effectively passivate the surface of the compound semiconductor material. The configuration including a dielectric layer, a barrier layer and a passivating layer reduces the diffusion of oxygen to the interface of the Si-passivating layer with the compound semiconductor, which may lead to potentially lower interface state densities.

Certain embodiments of the presented semiconductor structure and the method for fabricating a semiconductor structure may comprise individual or combined features, method steps or aspects as mentioned above or below with respect to exemplary embodiments.

### BRIEF DESCRIPTION OF THE DRAWINGS

In the following, embodiments of semiconductor structures and methods and devices relating to the manufacture of semiconductor structures are described with reference to the enclosed drawings.

FIG. 1 shows a schematic diagram of an embodiment of a semiconductor structure.

FIG. 2 shows a flow chart of method steps involved in a method for fabricating a semiconductor structure.

FIGS. 3-6 show schematic diagrams of an embodiment of a semiconductor structure and illustrate method steps involved in the fabrication of a semiconductor structure.

FIG. 7 shows a schematic diagram of a semiconductor device including an embodiment of the semiconductor structure.

FIG. 8 shows a schematic diagram of a field effect transistor device including an embodiment of the semiconductor structure.

FIG. 9 shows graphs depicting spectroscopic data of embodiments of semiconductor structures.

FIG. 10 shows graphs depicting capacitances and conductances of an embodiment of a semiconductor structure.

Like or functionally like elements in the drawings have been allotted the same reference characters, if not otherwise indicated.

### DETAILED DESCRIPTION OF THE EMBODIMENTS

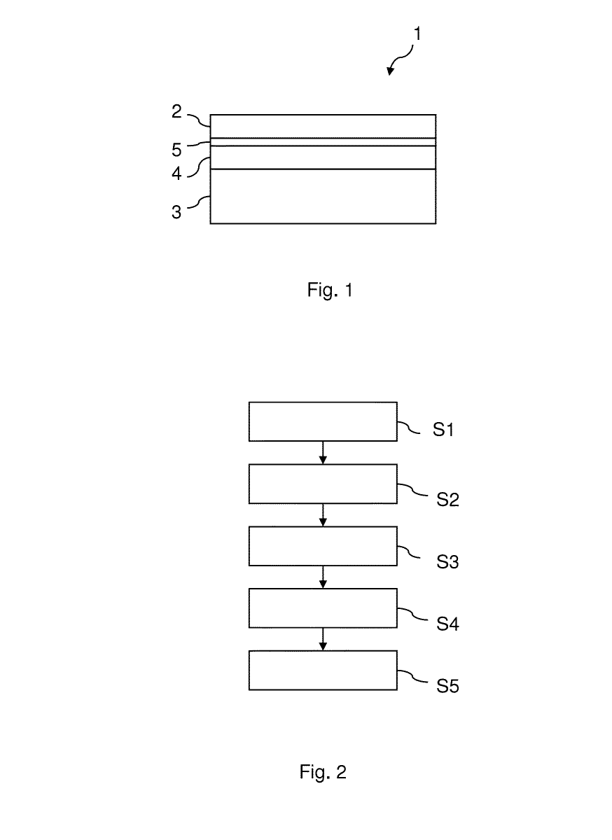

FIG. 1 shows a schematic diagram of an embodiment of a semiconductor structure. The general semiconductor structure 1 can be part of a semiconductor device or an integrated circuit chip. The semiconductor structure comprises a substrate 3, a passivation layer 4, a barrier layer 5, and a high-k dielectric layer 2.

Semiconductor substrate 3 is a III-V compound semiconductor, e.g. GaAs. In this disclosure, a III-V compound semiconductor material is a semiconductor material that includes at least one element or a mixture of elements from Group IIIA of the periodic table of elements and at least one element or a mixture of elements from Group VA of the periodic table of elements. Illustrative examples of III-V compound semiconductors that can be used as material for the substrate 3 include, but are not limited to: GaAs, InP, InAs, GaP, InSb, GaSb, GaN, InGaAs, and InAsSb. Preferably the III-V compound semiconductor is one of GaAs optionally including In, or one of InSb optionally including As. The substrate can be replaced by a hetero structure comprising semiconductor compound materials.

One may contemplate of several types of substrates. The substrate 3 can include a bulk wafer or a single layered material (as shown). However, also a III-V layer grown on another III-V bulk wafer can be used, e. g. InGaAs on InP. For example, the III-V compound semiconductor material can be a multilayered material including different III-V compound semiconductors stacked upon each other. In the multilayered embodiment, an upper layer of a III-V compound semiconductor is located on a lower layer of a different III-V compound material, wherein the upper layer has a wider-band gap than the lower layer. Some examples of such materials include, but are not limited to: an AlGaAs layer atop a InGaAs layer, a InGaP layer located atop a InGaAs layer, InAlAs layer atop a InGaAs layer, or a AlSb layer atop an InAsSb layer. A III-V layer may also be grown on a IV elemental semiconductor, e.g., GaP on Si or GaA on Ge or vice a versa.

The substrate may also be a III-V hetero-structure on III-V bulk wafer, a III-V layer or III-V hetero-structure integrated on Si, Ge, SiGe, or III-V layer or III-V hetero-structure integrated on a silicon and/or germanium on insulator structure (SOI, GOI, SGOI). As a representative example, in the following, GaAs is assumed as substrate material.

On one surface of the GaAs substrate 3 a Si passivation layer 4 having a dielectric constant of approximately κ=11, is located. The Si layer 4 can be formed by electron beam evaporation or any other known technique. The Si passivation layer 4 is covered with a barrier layer 5. The barrier layer 5 can be formed by electron beam evaporation or any other known technique. The barrier material can be considered a protecting film 5 preventing the amorphous Si from chemical reacting with the high-k dielectric layer 2 placed on the barrier layer 5. The dielectric layer 2 corresponds to a high-k gate dielectric.

The dielectric material has a dielectric constant of greater than that of silicon dioxide. The dielectric material employed may comprise any metal oxide or mixed metal oxide that is typically used as a gate dielectric or a capacitor dielectric in semiconductor device manufacturing. Examples of such dielectric material include, but are not limited to: Al₂O₃, AlON, Ta₂O₅, TiO₂, La₂O₃, SrTiO₃, LaAlO₃, ZrO₂, Y₂O₃, Gd₂O₃, MgO, MgNO, Hf-based materials and combinations including multilayers thereof.

The expression “Hf-based dielectric” as used herein to include any high k dielectric containing hafnium (Hf). Examples of such Hf-based dielectrics comprise hafnium oxide (HfO₂), hafnium silicate (HfSiOₓ), Hf silicon oxynitride (HfSiON), HfLaOx, HfLaSiOₓ, HfLaSiONₓ, or multilayers thereof. Typically, the Hf-based dielectric is hafnium oxide or hafnium silicate. Hf-based dielectrics typically have a dielectric constant that is greater than about 10.0. In the following, HfO₂ is assumed as dielectric material for the dielectric layer 2 in the semiconductor structure 1.

The physical thickness of the dielectric material 16 may vary, but typically, the dielectric layer 2 has a thickness from about 1 nm to about 7 nm. The dielectric material may be formed in-situ utilizing any conventional deposition process including, for example, chemical vapor deposition, PECVD, atomic layer deposition, chemical solution deposition, MOCVD, evaporation and other like deposition processes.

Usually, Si is thermodynamically unstable in contact with most of suitable high-k dielectrics including metal oxides MeO. Then, Si can react and form, e.g. SiO₂, silicate (MeₓSi_{y}O_{z}) or silicide MeₓSi_{y} or a combination thereof.

The barrier layer 5 is introduced in order to prevent an undesired reaction between the Si and the high-k metal oxide. The thin barrier layer 5 of approximately 1 nm or less is chemically stable against reaction with Si at the temperatures required by fabrication processing steps, as for example a gate stack deposition process or device processing. In addition, the barrier layer 5 may also reduce Si oxidation. As an example, the barrier interlayer 5 can consist of a thin Al₂O₃ layer typically having a thickness of approximately 1 nm or less (down to a few monolayers). E.g. Al₂O₃ is thermodynamically stable in contact with Si. However, the “barrier” interlayer can consist of any element or any binary or ternary compound which is thermodynamically stable in contact with Si. Examples of such materials include, but are not limited to Y₂O₃, Sc₂O₃, Gd₂O₃, Dy₂O₃, Lu₂O₃, Ce₂O₃, LaAlO and combinations thereof. In the following, Al₂O₃ is assumed as barrier material for the barrier layer 5.

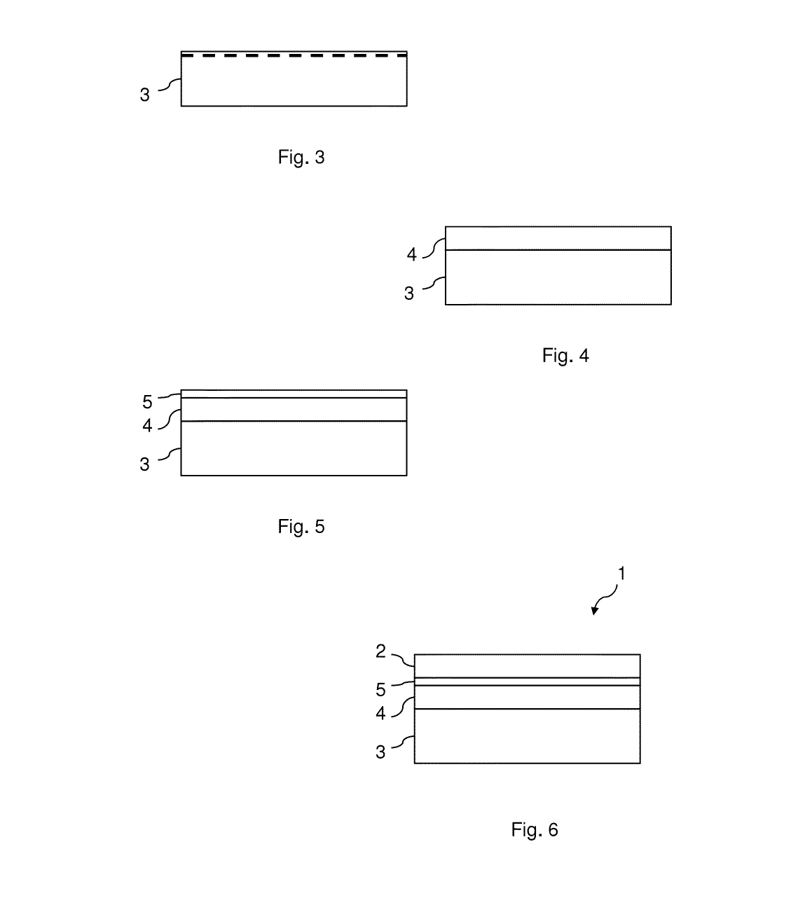

FIG. 2 shows a flow chart of method steps involved in a method for fabricating a semiconductor structure, and FIGS. 3-6 show schematic diagrams of an embodiment of a semiconductor structure for illustrating the fabrication method.

As shown in FIG. 3 a GaAs substrate 3 is provided (step S1). The substrate 3 is, for example, a (001) GaAs, which is fabricated by epitaxial growth and n- or p-doped. A doping can range between 1 10¹⁵ and 7 10¹⁷ cm ⁻³. As an optional process, included in the providing step S1, the substrate 3 is cleaned for removing native oxides. Potentially present Ga₂O₃ or As₂O₅ is removed from the compound semiconductor material of the substrate 3 by washing in an HF/H₂O solution which removes parts of the native oxides, and by utilizing an H plasma process. The respective wafer including the substrate 3 is dipped into a 5% HF/H₂O solution for about 30 seconds and transferred into a UHV chamber for the plasma treatment.

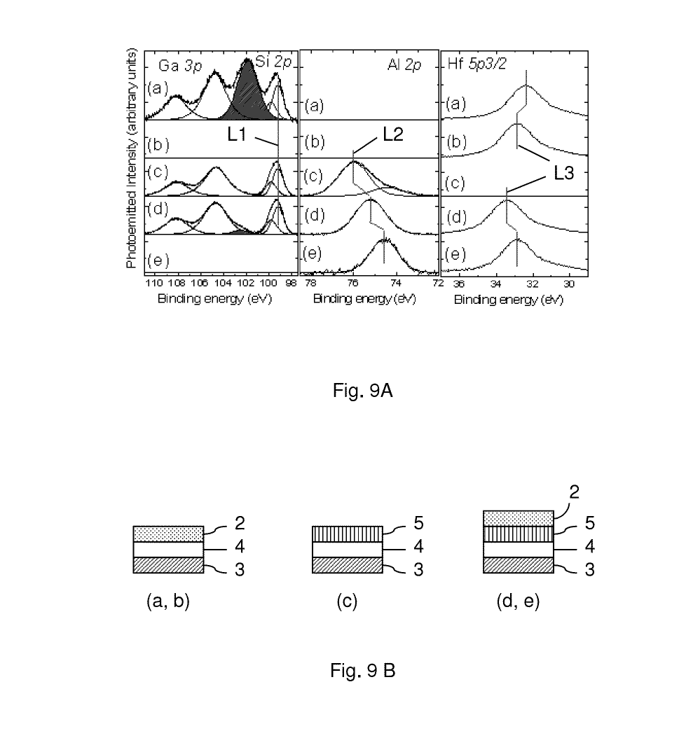

The H plasma process includes providing a plasma of hydrogen, H, using a hydrogen source such as, for example, molecular or, more preferably, atomic hydrogen. The hydrogen plasma is a neutral, highly ionized hydrogen gas of neutral atoms or molecules, positive ions and free electrons. Ionization of the hydrogen source is typically carried out in a reactor chamber in which the ionization process is achieved by subjecting the source to strong DC or AC electromagnetic fields. The wafer is exposed to a radio-frequency generated H plasma at a temperate of about 250° C. for approximately 30 minutes. As a result a clean preprocessed GaAs surface is generated. The removal of the native oxides is indicated by the appearance of a specific reflection high-energy electron diffraction (RHEED) pattern (see FIG. 9).

Next, as shown in FIG. 4, a step S2 of depositing a passivation material on the substrate 3 for forming a passivation layer 4 is performed. The passivation layer 4 is an amorphous Si layer. The thin layer of amorphous Si may have a thickness between 1 nm and 0.5 nm, and is deposited onto the clean substrate 3 in the UHV chamber. Si deposition is performed by e-beam evaporation of an elemental Si target and is run in the rf H plasma at approximately room temperature between 18° C. and 28° C. The deposition of the Si is carried out in-situ.

For screening the Si layer from potential metal oxides used as high-k dielectrics, a barrier layer is deposited (step S3). The thin barrier layer 5 consisting of Al₂O₃ and preferably having a thickness between 0.5 nm and 1.0 nm is deposited onto the Si-passivation layer 4. At a temperature of about kept 250° C. aluminum oxide deposition is performed by electron-beam evaporation of an Al₂O₃ target. The barrier layer 5 deposition is preferably done without additional oxygen supply. The resultant Al₂O₃/Si/GaAs structure is depicted in FIG. 5. Further, the structure is exposed to molecular oxygen at temperature of 250° C.

The high-k dielectric HfO₂ is deposited in the next process step S4. The high-k dielectric is deposited onto the Al₂O₃/Si/GaAs substrate kept at 250° C. under UHV. Depositing the HfO₂ may comprise electron beam evaporation of an Hf elemental source in the presence of molecular oxygen or of atomic oxygen generated by a radio-frequency plasma source. The dielectric layer 2 can be considered a gate oxide. The semiconductor structure 1 achieved is shown in FIG. 6 and corresponds to the structure indicated in FIG. 1.

The processing steps S1-S4 are performed without breaking the UHV in order to prevent contamination of the surfaces and oxidation of the substrate 3. However, variants of the manufacturing method may also include processing steps that are performed ex-situ.

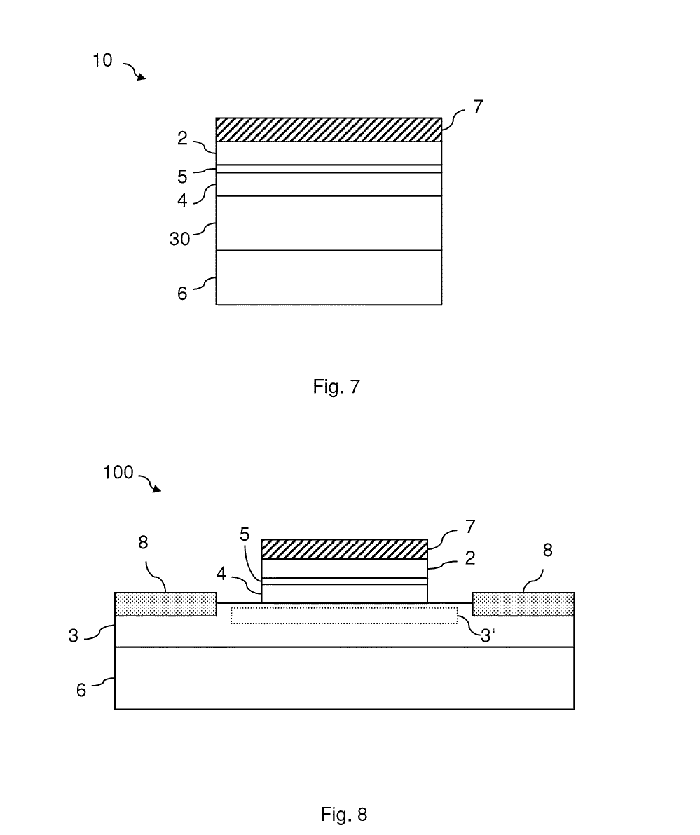

Alternatively or additionally to the steps indicated above, the semiconductor substrate can be structured as a hetero structure for manufacturing electronic components, like integrated circuits. FIG. 7 is a pictorial representation of a section of a gate stack 10 based on a III-V semiconductor hetero structure 30. The hetero structure 30 is patterned on an appropriate substrate 6 as explained above.

For providing gate and/or source drain contacts metal contacts are deposited as indicated in FIG. 2 as method step S5. In FIG. 7 a gate contact 7 is placed onto the high-k dielectric layer 2 acting as gate oxide. One method which could be used for this deposition is molecular beam epitaxy (MBE), which has the advantage of enabling the deposition of very small amount of material at temperatures as low as room temperature. However, other known methods for fabricating gate contact can be contemplated. The gate stack 10 can be further processed to form desired components.

For example, the HfO₂/Al₂O₃/Si/III-V multilayered structure 1 is processed into MOS capacitors. Therefore, a 200 nm thick W metal gate 7 is deposited in a sputtering process. A post-metallization annealing step may be performed in N₂ at a predetermined temperature for a specified time. For example, temperatures of about 400° C., 500° C., 550° C. for 30 minutes can be chosen. Contact pads may be obtained by known lithographic techniques.

For a 2 nm HfO₂/1 nm Al₂O³/1 nm Si/p-GaAs gate stack 10 similar to the representation of FIG. 7 the capacitance is typically about 3 μF/cm². This corresponds to an equivalent oxide thickness of 1.2 nm The improved capacitance with respect to conventional configurations may likely be due to the insertion of the barrier layer 5 in the gate structure.

The structures shown in FIG. 1 or 6 can be used in fabricating a metal oxide semiconductor capacitor (MOSCAP) as shown in FIG. 7 and/or a MOSFET utilizing conventional processes. One example of a MOSFET is shown in FIG. 8. The FET 100 is fabricated on a III-V compound semiconductor substrate 6 which can be a bulk compound. The active substrate layer 3 is n- or p-doped III-V compound semiconductor material. Reference character 3′ denotes the channel region of the semiconductor material, e.g. GaAs, below the gate 7 and the gate dielectric 2. Laterally source/drain diffusion regions 8 are shown. In each case, an electrode or an electrode stack is formed on the material stacks shown in FIG. 1, 6 or 7, and thereafter these materials layers are patterned by lithography and etching.

The electrode or electrode stack, which comprises at least one conductive material, is formed utilizing a known deposition process such as, for example, physical or chemical vapor deposition, or evaporation. The conductive material used as the electrode includes, but is not limited to: Si-containing materials such as Si or a SiGe alloy layer in single crystal, polycrystalline or amorphous form. The conductive material may also be a conductive metal or a conductive metal alloy. Combinations of the aforementioned conductive materials are also feasible.

The thickness, i.e. height, of the electrode deposited may vary depending on the deposition process and material employed. For example, a 200 nm thick W gate electrode formed by dc sputtering utilizing photolithography and dry etching in SF₆ can be used. Also Al gates having thicknesses of approximately 300 nm and formed by electron beam evaporation through shadow masks can be envisaged.

An annealing step can be performed before or after the deposition of the gate electrode. Said anneal step is typically performed in a nitrogen atmosphere between 500° C. and 800° C.

The MOSFET formation may include forming isolation regions, such as trench isolation regions, within the III-V compound semiconductor material 3. Following patterning of the material stack, sometimes a spacer is formed on exposed sidewalls of each patterned material stack 4, 5, 2, 7. The width is preferably sufficient such that the source and drain contacts 8 do not reach underneath the edges of the patterned material stack 4, 5, 2, 7.

A passivation step can be added by subjecting the structure 100 to a thermal oxidation, nitridation or oxy-nitridation process. The passivation step forms a thin layer of passivating material about the material stack. Typically, source/drain diffusion regions 8 are then formed into the substrate 3. For example, the source/drain diffusion regions 8 are formed utilizing ion implantation and an annealing step.

The embodiments of the proposed semiconductor structures provide for highly miniaturized gate stacks that may be employed to fulfill ITRS specifications.

### EXAMPLES

FIG. 9A shows graphs depicting spectroscopic data of embodiments of semiconductor structures. In FIG. 9B the investigated structures a depicted. The graphs in FIG. 9A correspond to X-ray photoelectron spectroscopy data. The columns show Ga3p, Si2p, Al2p and Hf5p core level spectra as a function of the binding energy each. The vertical lines L1, L2, L3 indicate a shift of the photoemission peaks a depending on the examined stack structure and fabrication process stage.

Curves relating to (a) refer to a gate structure on GaAs without barrier layer: the high-k dielectric 2, in this case HfO₂, is deposited directly on a thin Si-passivating layer 4 on a GaAs substrate 3.

Curves relating to (b) refer to the standard HfO₂/Si passivating layer/GaAs gate structure after annealing at 700° C. in N₂ for 5 seconds. One can observe that the Hf5p3/2 peak for (b) shifts towards a higher binding energy with respect to the Hf5p3/2 peak for (a). This is indicative for HfₓSi_{y}O_{z} formation upon the thermal treatment.

Curves relating to (c) refer to a material stack structure as shown in FIG. 5: a thin Al₂O₃ barrier layer 5 is deposited on a thin Si passivating layer 4 on a GaAs substrate 3. One notes the absence of any SiOₓ peak at binding energies of approximately 100 eV-102 eV which is indicated as a black peak, in particular, in the spectra relating to (a). Further, the position of the Al2p peak indicates that the thin Al₂O₃ barrier layer 5 does not react with the Si passivating layer 4 during deposition. Hence, no silicate forms during the deposition of the Al2O₃ barrier layer.

Curves relating to (d) refer to a material stack structure as shown in FIG. 6: a HfO₂ dielectric layer 2 is deposited on the Al₂O₃ barrier layer/Si passivating layer/GaAs substrate 5, 4, 3. One observes that the Al2p peak in shifts towards lower binding energies with respect to the Al2p peak in (c) where no HfO₂ is present. This indicates that no reaction between the Al₂O₃ barrier and the Si, in particular in terms of silicate formation, takes place at this stage.

Curves relating to (e) refer to the gate stack structure HfO₂/Al₂O₃/Si/GaAs that was annealed at 700° C. in N₂ for 5 seconds. The Al2p peak in (e) further shifts towards lower binding energies with respect to the Al2p peak in (d) indicating that no Al-silicate forms upon the thermal treatment. The Hf 5p3/2 peak in (e) also shifts towards lower binding energies with respect to the Hf 5p3/2 peak in (d) indicating that no Hf-silicate forms upon thermal treatment.

The experimental data shown in FIG. 9 support that the thin Al₂O₃ bather layer between the high-k dielectric and the Si-passivated GaAs substrate suppresses chemical reactions between the Hf-based high-k dielectric and the Si-passivated substrate. In particular, the barrier layer prevents the formation of Hf—Si compositions at temperatures used in semiconductor device fabrication, e.g. between 10° C. and 800° C., or more preferably between 20° C. and 900° C. Additionally, the amorphous Si material is shielded against oxidation by oxygen diffusion through the dielectric which would have deteriorating effects on the capacitance of the stack.

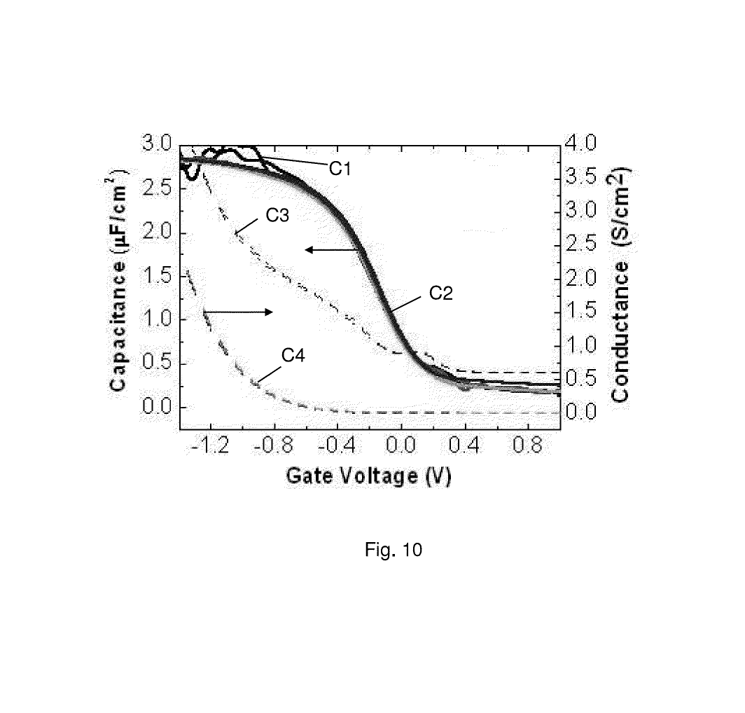

FIG. 10 shows the capacitance as a function of gate voltage of a MOSCAP structure comprising 2 nm HfO₂/1 nm Al₂O³/1 nm Si/p-GaAs at 1 kHz, 10 kHz, 100 kHz (curves C2) and 1 MHz (curve C1). Specifically, the capacitance curves have low frequency dispersion, which is indicative of a low interface state density. The capacitance in accumulation is about 3 μF/cm² which corresponds to a capacitance equivalent thickness (CET) of 1.2 nm. This resultant capacitance value exceeds the capacitance of conventional Si-passivated III-V based devices. FIG. 10 also shows the conductance as a function of the gate voltage on the right scale (curve C4). One can see that leakage is reasonably suppressed in the embodiment of a gate stack. In summary, the disclosed gate stack structures, devices and arrangements are promising candidates for meeting future ITRS requirements.

The disclosed semiconductor structures can be part of a semiconductor chip. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either an intermediate product, such as a motherboard, or an end product. The end product can be any product that includes integrated circuit chips, ranging from toys and other low-end applications to advanced computer products having a display, a keyboard or other input device, and a central processor.

The work leading to this invention has received funding from the European Union

Seventh Framework Programme (FP7/2007-2013) under grant agreement no. 255298.

### LIST OF REFERENCE CHARACTERS

1 semiconductor structure
2 dielectric layer
3 channel region
4 passivation layer
5 barrier layer
6 substrate
7 gate arrangement
8 source/drain contact
10 gate stack structure
30 compound semiconductor hetero structure
100 field effect transistor
C1, C2 capacitance curve
C3, C4 conductance curve
L1, L2, L3 peak shift indicating line
S1-S5 method steps

1. A semiconductor structure comprising:
a dielectric layer including a dielectric material having a dielectric constant higher than that of silicon oxide;
a channel region including a compound semiconductor material;
a passivation layer including a passivation material between the channel region and the dielectric layer; and
a barrier layer including a barrier material between the dielectric layer and the passivation layer for reducing a chemical reaction of the dielectric material of the dielectric layer with the passivation material of the passivation layer, wherein said barrier layer is a metal oxide or a metal nitride containing a metal selected from the group consisting of Y, Sc, Gd, Dy, La, Lu, Ce and LaAl.

2. The semiconductor structure of claim 1, wherein the compound semiconductor material of the channel region includes a III-V compound semiconductor material, a II-VI compound semiconductor material, and/or a IV-IV compound semiconductor material, or any hetero structure thereof

3. The semiconductor structure of claim 1, wherein the passivation material of the passivation layer includes amorphous silicon.

4. (canceled)

5. The semiconductor structure of claim 1, wherein the dielectric material of the dielectric layer includes a hafnium-based dielectric.

6. The semiconductor structure of claim 1, further comprising a gate arrangement located on the dielectric layer.

7. The semiconductor structure of claim 6, wherein a capacitance between the gate arrangement and the channel region is greater than 2 microfarad per square centimeter.

8. The semiconductor structure of claim 1, wherein the barrier layer has thickness of less than 1 nanometer.

9. The semiconductor structure of claim 1, wherein the passivation layer has a thickness of less than 1 nanometer.

10. The semiconductor structure of claim 1, wherein the dielectric layer has a thickness between 1 and 10 nanometers.

11. A method for fabricating a semiconductor structure comprising:
providing (Si) a substrate (6, 3) including a compound semiconductor material;
depositing (S2) a passivation material on the substrate (3) for forming a passivation layer (4);
depositing (S3) a barrier material on the passivation layer (4) for forming barrier layer (5); and
depositing (S4) a dielectric material having a dielectric constant that is greater than that of silicon oxide on the barrier layer (5) for forming a dielectric layer (2);
wherein the barrier material is adapted to reduce a chemical reaction of the dielectric material of the dielectric layer (2) with the passivation material of the passivation layer (4).

12. The method of claim 11, further comprising processing the substrate (6, 3) for forming a hetero structure (30).

13. The method of claim 11, further comprising depositing (S5) a conducting material on the dielectric layer (2) and/or on the substrate (6, 3) for forming contacts (7, 8).

14. The method of claim 11, further comprising: cleaning the substrate (6, 3) including exposing the substrate (6, 3) with hydrogen fluoride and/or exposing the substrate (6, 3) to a hydrogen plasma.

15. The method of claim 11, wherein the method is performed in-situ in an ultra high vacuum.

16. The semiconductor structure of claim 1, wherein said barrier layer is a metal nitride.

17. A semiconductor structure comprising:
a dielectric layer including a dielectric material having a dielectric constant higher than that of silicon oxide;
a channel region including a compound semiconductor material;
a passivation layer including a passivation material between the channel region and the dielectric layer; and
a barrier layer including a barrier material between the dielectric layer and the passivation layer for reducing a chemical reaction of the dielectric material of the dielectric layer with the passivation material of the passivation layer, wherein said barrier layer contains aluminum nitride.
